(19) United States
(12) Patent Application Publication
(10) Pub. No.: US 2008/0074038 A1
(43) Pub. Date: Mar. 27, 2008

(54) Organic light emitting display (OLED) and its method of manufacture

(76) Inventors: Hee-Kyung Kim, Yongin-si (KR); Shinichiro Tamura, Yongin-si (KR); Das Rupasree Ragini, Yongin-si (KR); Young-Hun Byun, Yongin-si (KR); O-Hyun Kwon, Yongin-si (KR); Che-Un Yang, Yongin-si (KR); Young-Mok Son, Yongin-si (KR)

Correspondence Address: Robert E. Bushnell, Suite 300, 1522 K Street, N.W., Washington, DC, 20005-1202, US

(21) Appl. No.: 11/819,139

(22) Filed: Jun. 25, 2007

(30) Foreign Application Priority Data
Sep. 26, 2006 (KR) 10-2006-0093718

(51) Int. Cl. H01J 1/62; H01J 9/02; H01L 51/54; H01L 51/56

(52) U.S. Cl. 313/504; 445/24

(57) ABSTRACT

An Organic Light Emitting Display (OLED) and a method of manufacturing the OLED includes: a first electrode arranged on a substrate; a Hole Transporting Layer (HTL) arranged on the first electrode; a light Emitting Layer (EL) arranged on the HTL; an Electron Transporting Layer (ETL) arranged on the light EL; and a second electrode arranged on the ETL; the light EL includes a soluble hole transporting host, a soluble electron transporting host, and a soluble light emitting dopant; a difference of a Highest Occupied Molecular Orbital (HOMO) level between the HTL and the hole transporting host respectively and the light emitting dopant is 1 eV or less; a difference of a HOMO level between the HTL and the hole transporting host respectively and the electron transporting host is 0.5eV or more; a difference of a Lowest Unoccupied Molecular Orbital (LUMO) level between the ETL and the electron transporting host respectively and the light emitting dopant is 1 eV or less; and a difference of a LUMO level between the ETL and the electron transporting host respectively and the hole transporting host is 0.5 eV or more.

### CLAIM OF PRIORITY

This application makes reference to, incorporates the same herein, and claims all benefits accruing under 35 U.S.C.§119 from an application for ORGANIC LIGHT EMITTING DISPLAY AND METHOD OF MANUFACTURING THE SAME earlier filed in the Korean Intellectual Property Office on the 26^{th} of September 2006 and there duly assigned Serial No. 10-2006-0093718.

### BACKGROUND OF THE INVENTION

1. Field of the Invention

The present invention relates to an Organic Light Emitting Display (OLED), and more particularly, the present invention relates to an OLED which can readily be manufactured in a large screen size and has a high luminous efficiency and its method of manufacture.

2. Description of the Related Art

An Organic Light Emitting Display (OLED) is an emissive display that uses a phenomenon of generating light by combining electrons and holes in a fluorescent or a phosphorus organic compound thin film (hereinafter, organic film) when a current flows in the organic film.

An OLED generally has a structure in which an anode, a hole transporting layer, a light emitting layer, an electron transporting layer, and a cathode are sequentially formed on a substrate.

As the increase in demand for a large screen sized display, research for increasing the screen size of the OLED has been actively conducted. In order to increase the screen size of the OLED, the uniformity of thickness of the organic film is very important. It is difficult to form a large size organic film having a uniform thickness using the conventional evaporation deposition method. Therefore, recently, a method of forming the organic film using a solution process has been proposed. The solution process is a coating process in which a polymer light emitting material having high solubility dissolved in a solvent is coated using spin coating or inkjet printing.

The research regarding the manufacture of an OLED using the solution process is focused on a polymer light emitting material having high solubility and good characteristics for forming thin film. However, the OLED that uses such a polymer light emitting material (hereinafter, a polymer OLED) has a lower luminous efficiency as compared to an OLED that uses a small molecule light emitting material (hereinafter, a small molecule OLED), and has a shortened lifespan due to the degradation of the polymer. This is because, due to the characteristics of the polymer, defects that accelerate the degradation of the polymer during a synthetic process remain in the molecular chain of the polymer and the purification thereof and forming a high purity light emitting layer are difficult.

The small molecule OLED has a higher luminous efficiency as compared to the polymer OLED, the purification thereof and forming a high purity light emitting layer are easy, and color pixels of three basic colors can be readily realized. However, a light emitting layer of the small molecule OLED is more difficult to manufacture than a light emitting layer of the polymer OLED using the solution process. So far, the research with respect to the manufacturing the small molecule OLED using the solution process is in an early stage.

The small molecule OLEDs manufactured using the solution process have been recently reported, but the luminous efficiency cannot reach the luminous efficiency of the small molecule OLED manufactured using a conventional deposition process.

Therefore, there is a need to develop a phosphorus OLED having a higher luminous efficiency using a small molecule based solution process than the luminous efficiency of the small molecule OLED manufactured using a conventional deposition process.

### SUMMARY OF THE INVENTION

The present invention provides an Organic Light Emitting Display (OLED) that has a long lifespan, can be manufactured in a large screen size, and has a high luminous efficiency and has a light emitting layer that can be readily manufactured using a solution process.

The present invention also provides a method of manufacturing such an OLED.

According to one aspect of the present invention, an Organic Light Emitting Display (OLED) is provided including: a first electrode arranged on a substrate; a Hole Transporting Layer (HTL) arranged on the first electrode; a light Emitting Layer (EL) arranged on the HTL; an Electron Transporting Layer (ETL) arranged on the light EL; and a second electrode arranged on the ETL; the light EL includes a soluble hole transporting host, a soluble electron transporting host, and a soluble light emitting dopant; a difference of a Highest Occupied Molecular Orbital (HOMO) level between the HTL and the hole transporting host respectively and the light emitting dopant is 1 eV or less; a difference of a HOMO level between the HTL and the hole transporting host respectively and the electron transporting host is 0.5 eV or more; a difference of a Lowest Unoccupied Molecular Orbital (LUMO) level between the ETL and the electron transporting host respectively and the light emitting dopant is 1 eV or less; and a difference of a LUMO level between the ETL and the electron transporting host respectively and the hole transporting host is 0.5 eV or more.

The light EL preferably includes a small molecule material.

The HOMO level of the electron transporting host is preferably lower than the HOMO level of the HTL by 0.5 eV or more.

The LUMO level of the hole transporting host is preferably higher than the LUMO level of the electron transporting layer by 0.5 eV or more.

At least one of the electron transporting host and the Electron Transporting Layer preferably includes a material selected from a group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

At least one of the electron transporting host and the ETL preferably includes a material selected from a group consisting of TPBi, PBD, BCP, BAlq, and OXD7.

The electron transporting host and the ETL preferably include a same material.

At least one of the hole transporting host and the HTL preferably includes a material selected from a group consisting of an oxadiazole compound having an amino substituent, a triphenylmethane compound having an amino substituent, a tertiary compound, a hydazone compound, a pyrazoline compound, an enamine compound, a styryl compound, a stilbene compound, and a carbazole compound.

At least one of the hole transporting host and the HTL preferably includes a material selected from a group consisting of TBADN, NPB, TPD, Spiro-NPB, DMFL-NPB, DPFL-NPB, and mHOST5.

The hole transporting host and the HTL preferably include a same material.

The HTL preferably includes a mixture film of PEDOT and PSS.

The light EL preferably further includes a third soluble host to improve the characteristics of forming a thin film.

The third soluble host preferably includes one of TPBi, TBADN, and mHOST5.

The light emitting dopant preferably includes either an organic molecule or an organic-metal complex having either fluorescent or phosphorus characteristics.

A content of the light emitting dopant in the light EL is preferably in a range of 0.1 to 50 wt %.

The light emitting dopant preferably includes one of Irpiq3 and BY4m.

A ratio of a thickness of the light EL to a thickness of the electron transporting layer is preferably in a range of from 1:100 to 100:1.

The OLED preferably further includes a Hole Injection Layer (HIL) arranged between the first electrode and the HTL.

The OLED preferably further includes an Electron Injection Layer (EIL) arranged between the ETL

According to another aspect of the present invention, an Organic Light Emitting Display (OLED) is provided including: a first electrode arranged on a substrate; a Hole Transporting Layer (HTL) arranged on the first electrode; a light Emitting Layer (EL) arranged on the HTL; and a second electrode arranged on the light EL; the light EL includes a soluble hole transporting host, a soluble electron transporting host, and a soluble light emitting dopant; a difference of a Highest Occupied Molecular Orbital (HOMO) level between the HTL and the hole transporting host respectively and the light emitting dopant is 1 eV or less; a difference of a HOMO level between the HTL and the hole transporting host respectively and the electron transporting host is 0.5 eV or more; a difference of a Lowest Unoccupied Molecular Orbital (LUMO) level between the electron transporting host and the light emitting dopant is 1 eV or less; and a difference of a LUMO level between the electron transporting host and the hole transporting host is 0.5 eV or more.

According to yet another aspect of the present invention, a method of manufacturing an Organic Light Emitting Display (OLED) is provided, the method including: forming a first electrode on a substrate; forming a Hole Transporting Layer (HTL) on the first electrode; forming a light Emitting Layer (EL) on the HTL using a solution process; forming an Electron Transporting Layer (ETL) on the light EL; and forming a second electrode on the ETL; forming the light EL includes forming a mixed solution containing a soluble hole transporting host, a soluble electron transporting host, and a soluble light emitting dopant; a difference of a Highest Occupied Molecular Orbital (HOMO) level between the HTL and the hole transporting host respectively and the light emitting dopant is 1 eV or less; a difference of a HOMO level between the HTL and the hole transporting host respectively and the electron transporting host is 0.5 eV or more; a difference of a Lowest Unoccupied Molecular Orbital (LUMO) level between the electron transporting layer and the electron transporting host respectively and the light emitting dopant is 1 eV or less; and a difference of a LUMO level between the electron transporting layer and the electron transporting host respectively and the hole transporting host is 0.5 eV or more.

The light EL is preferably formed of a small molecule material.

The solution process is preferably selected from a group consisting of spin coating, inkjet printing, gravure printing, roll to roll processing, syringe injection, dip coating, spray coating, relief printing, lithography printing, flexography printing, and screen printing.

At least one of the electron transporting host and the electron transporting layer is preferably formed of a material selected from a group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

At least one of the electron transporting host and the electron transporting layer is preferably formed of a material selected from a group consisting of TPBi, PBD, BCP, BAlq, and OXD7.

At least one of the hole transporting host and the HTL is preferably formed of a material selected from a group consisting of an oxadiazole compound having an amino substituent, a triphenylmethane compound having an amino substituent, a tertiary compound, a hydazone compound, a pyrazoline compound, an enamine compound, a styryl compound, a stilbene compound, and a carbazole compound.

At least one of the hole transporting host and the HTL is preferably formed of a material selected from a group consisting of TBADN, NPB, TPD, Spiro-NPB, DMFL-NPB, DPFL-NPB, and mHOST5.

The light EL preferably further includes a third soluble host to improve the characteristics of forming a thin film.

The third soluble host preferably includes one of TPBi, TBADN, and mHOST5.

The HTL is preferably formed of a mixture film of PEDOT and PSS.

The light emitting dopant is preferably either an organic molecule or an organic-metal complex having either fluorescent or phosphorus characteristics.

The light emitting dopant is preferably one of Irpiq3 and BY4m.

According to still another aspect of the present invention, a method of manufacturing an Organic Light Emitting Display (OLED) is provided, the method including: forming a first electrode on a substrate; forming a Hole Transporting Layer (HTL) on the first electrode; forming a light Emitting Layer (EL) on the HTL using a solution process; and forming a second electrode on the light EL; forming the light EL includes forming a mixed solution containing a soluble hole transporting host, a soluble electron transporting host, and a soluble light emitting dopant; a difference of a Highest Occupied Molecular Orbital (HOMO) level between the HTL and the hole transporting host respectively and the light emitting dopant is 1 eV or less; difference of a HOMO level between the HTL and the hole transporting host respectively and the electron transporting host is 0.5 eV or more; a difference of a Lowest Unoccupied Molecular Orbital (LUMO) level between the electron transporting host and the light emitting dopant is 1 eV or less; and a difference of a LUMO level between the electron transporting host and the hole transporting host is 0.5 eV or more.

According to the present invention, the light emitting layer is readily manufactured using a solution process, the lifespan of the OLED is increased, a large screen size OLED is readily manufactured, and the luminous efficiency of the OLED is increased.

### BRIEF DESCRIPTION OF THE DRAWINGS

A more complete appreciation of the present invention and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a cross-sectional view of an Organic Light Emitting Display (OLED) and a method of manufacturing the OLED according to a first embodiment of the present invention;

FIG. 2 is a cross-sectional view of an OLED and a method of manufacturing the OLED according to a second embodiment of the present invention;

FIG. 3 is a cross-sectional view of an OLED and a method of manufacturing the OLED according to a third embodiment of the present invention;

FIG. 4 is a cross-sectional view of an OLED and a method of manufacturing the OLED according to a fourth embodiment of the present invention;

FIG. 5 is a cross-sectional view of an OLED and a method of manufacturing the OLED according to fifth through seventh embodiments of the present invention;

FIG. 6 is a schematic drawing showing HOMO and LUMO levels of each of a hole transporting layer, an electron transporting host, a hole transporting host, and dopant and an electron transporting layer of OLEDs according to first through seventh embodiments of the present invention;

FIG. 7 is a graph showing the variation of current density with respect to a voltage applied to the OLEDs according to first and second embodiments of the present invention;

FIG. 8 is a graph showing the variation of brightness with respect to a voltage applied to the OLEDs according to first and second embodiments of the present invention;

FIG. 9 is a graph showing the variation of current efficiency with respect to brightness of the OLEDs according to first and second embodiments of the present invention;

FIGS. 10 and 11 are graphs showing the variation of current efficiency with respect to a voltage applied to the OLEDs according to third and fourth embodiments of the present invention; and

FIG. 12 is a graph showing the variation of current efficiency with respect to a voltage applied to the OLEDs according to fifth through seventh embodiments of the present invention.

### DETAILED DESCRIPTION OF THE INVENTION

An Organic Light Emitting Display (OLED) and a method of manufacturing the OLED according to the present invention is described more fully below with reference to the accompanying drawings in which exemplary embodiments of the present invention are shown. In the drawings, the thicknesses of layers and regions are exaggerated for clarity.

### Embodiment 1

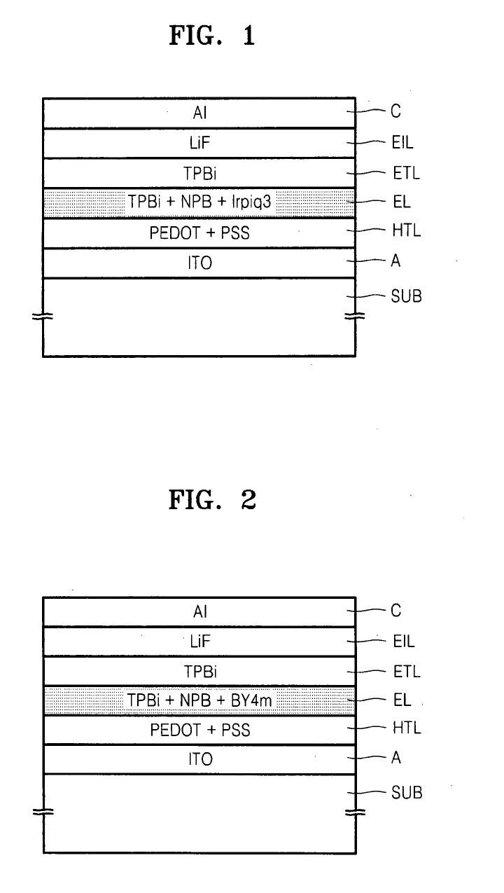

FIG. 1 is a cross-sectional view of an OLED and a method of manufacturing the OLED according to a first embodiment of the present invention.

Referring to FIG. 1, an anode A is formed on a substrate SUB. The anode A is formed of Indium Tin Oxide (ITO) serving as a first electrode. A Hole Transporting Layer (HTL) is formed on the anode A. The Hole Transporting Layer (HTL) is a composite layer made of PEDOT and PSS. The Hole Transporting Layer (HTL) is formed by baking a bare coating layer that includes PEDOT and PSS at a temperature of 180° C. for approximately one hour after the bare coating layer has been formed to a thickness of 50 nm. Next, a light emitting layer EL is formed on the Hole Transporting Layer (HTL). The light emitting layer EL includes a small molecule host and a light emitting dopant. The small molecule host includes at least an electron transporting host E-host and a hole transporting host H-host. The light emitting dopant is an organic molecule or organic-metal complex having a fluorescent or phosphorus characteristic, for example, Irpiq3. The content of the light emitting dopant in the light emitting layer EL is 5 wt %. The method of forming the light emitting layer EL is described later.

Next, an Electron Transporting Layer (ETL) is formed on the light emitting layer EL using a thermal evaporation method.

An Electron Injection Layer (EIL) and a cathode C are sequentially formed on the Electron Transporting Layer (ETL). The cathode C is formed of aluminium serving as a second electrode. The cathode C is formed to a thickness of approximately 150 nm. The Electron Injection Layer (EIL) is a LiF layer and is formed to a thickness of approximately 0.8 nm. The formation of the Electron Injection Layer (EIL) is optional. Therefore, the formation of the Electron Injection Layer (EIL) can be omitted in the process of sequentially forming the Electron Transporting Layer (ETL), the Electron Injection Layer (EIL), and the cathode C.

Although it is not depicted in FIG. 1, a Hole Injection Layer (HIL) can further be formed between the anode A and the Hole Transporting Layer (HTL). The formation of the Hole Injection Layer (HIL) is optional. Therefore, the formation of the Hole Injection Layer (HIL) can be omitted in the process of sequentially forming the anode A, the Hole Injection Layer (HIL), and the Hole Transporting Layer (HTL).

The light emitting layer EL is formed using a spin coating process. That is, after a mixed solution made by dissolving the small molecule host in an organic solvent and adding a light emitting dopant is spin coated on the Hole Transporting Layer (HTL), the light emitting layer EL is formed by baking the spin coated film. The organic solvent is 1,2-dichloroethane. When the light emitting layer EL and the Electron Transporting Layer (ETL) are formed, the light emitting layer EL and the Electron Transporting Layer (ETL) may be formed to a thickness that can maximize the resonance effect of light generated by the light emitting layer EL.

The small molecule host includes an electron transporting host E-host having a Highest Occupied Molecular Orbital (HOMO) level lower than the Hole Transporting Layer (HTL), and includes a hole transporting host H-host having a Lowest Unoccupied Molecular Orbital (LUMO) level higher than the Electron Transporting Layer (ETL). The small molecule host according to the first embodiment of the present invention includes TPBi as the electron transporting host E-host and NPB as the hole transporting host H-host.

The small molecule host can further include a third soluble host besides the electron transporting host E-host and the hole transporting host H-host. When the light emitting layer EL is formed using the third soluble host, a thin film forming characteristic is improved.

The small molecule host can be a mixture that includes two kinds of small molecule materials (hereinafter, a two component host) or can be a mixture that includes three kinds of small molecule materials (hereinafter, a three component host).

The combinations of the hosts are summarized in Table 1 and Table 2. Table 1 shows the combinations of two component hosts and Table 2 shows the combinations of three component hosts.

In the OLED and a method of manufacturing the OLED according to the present embodiment, the small molecule host can be one of the two component or three component hosts indicated in Tables 1 and 2. The small molecule host used in the first embodiment of the present invention is A3 in Table 1.

The hosts indicated in Tables 1 and 2 can also be used in light emitting layers of the OLEDs according to the second through seventh embodiments of the present invention, which are described later.

TPBi: 1,3,5-tris(N-phenylbenzimidazol-2,yl)benzene

PBD: 2-(4-Biphenylyl)-5-(4-tert-butylphenyl)-1,3,4-oxadiazole

BCP: 2,9-Dimethyl-4,7-diphenyl-1,10-phenanhro-line

BAlq: Bis-(2-methyl-8-quinolinolate)-4-(phenylphenolato)aluminium

OXD7: 1,3-bis(N,N-t-butyl-phenyl)-1,3,4-oxadiazole

TBADN: 3-Tert-butyl-9,10-di(naphth-2-yl)anthracene

NPB: N,N′-bis(1-naphtalenyl)-N-N′-bis(phenyl-benzidine)

TPD: N,N′-bis(3-methylphenyl)-N,N′-bis(phenyl)-benzidine

Spiro-NPB: N,N′-di(naphthalen-1-yl)-N,N′-diphenyl-spiro

DMFL-NPB: N,N′-di(naphthalene-1-yl)-N,N′-diphenyl-9,9′-dimethyl-fluorene

DPFL-NPB: N,N′-di(naphthalen-1-yl)-N,N′-diphenyl-9,9′-diphenyl-fluorene

mHOST5: 2,7-Di(N,N′-carbarzolyl)-9,9-bis[4-(2-ethylhexyloxy)-phenyl]fluorene

TABLE 1

| | Host | |
|---|---|---|
| | Electron transporting | |
| Combination | hosts | Hole transporting hosts |
| A1 | TPBi | TBADN |
| A2 | PBD | TBADN |
| A3 | TPBi | NPB |
| A4 | TPBi | TPD |
| A5 | TPBi | mHOST5 |
| A6 | PBD | mHOST5 |
| A7 | TPBi | Spiro-NPB |
| A8 | TPBi | DMFL-NPB |
| A9 | TPBi | DPFL-NPB |

TABLE 2

| | Host | | |
|---|---|---|---|
| | Electron | Hole | Hosts for improving |
| | transporting | transporting | characteristics of forming |
| Combination | hosts | hosts | thin film |
| B1 | TPBi | NPB | mHOST5 |
| B2 | TPBi | TPD | mHOST5 |
| B3 | PBD | NPB | mHOST5 |
| B4 | PBD | TPD | mHOST5 |
| B5 | OXD7 | TPD | mHOST5 |
| B6 | OXD7 | NPB | mHOST5 |
| B7 | TPBi | Spiro-NPB | mHOST5 |
| B8 | TPBi | DMFL-NPB | mHOST5 |
| B9 | TPBi | DPFL-NPB | mHOST5 |

TPBi and TBADN have a function to improve in the characteristics of forming a thin film. mHOST5 is an electron transporting host and a host for improving the characteristics of forming a thin film.

Although it is not shown in Tables 1 and 2, BCP and BAlq can also be used as an electron transporting host E-host. Also, although it is not TPBi, PBD, BCP, BAlq, or OXD7, any compound that belongs to one of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound can be used as the electron transporting host E-host or the Electron Transporting Layer (ETL).

Also, although it is not TBADN, NPB, TPD, Spiro-NPB, DMFL-NPB, DPFL-NPB, or mHOST5, any compound that belongs to an oxadiazole compound having an amino substituent, a triphenylmethane compound having an amino substituent, a tertiary compound, a hydazone compound, a pyrazoline compound, an enamine compound, a styryl compound, a stilbene compound, and a carbazole compound can be used as the hole transporting host H-host or the Hole Transporting Layer (HTL).

The hosts are small molecule materials having high solubility. Accordingly, the light emitting layer in the OLED according to the first embodiment of the present invention can be readily formed using a solution process which is advantageous for manufacturing a large screen size. Therefore, according to the first embodiment of the present invention, the manufacture of an OLED that can be manufactured by a small molecule based solution process and has a very high luminous efficiency can be realized.

### Embodiment 2

FIG. 2 is a cross-sectional view of an OLED and a method of manufacturing the OLED according to a second embodiment of the present invention.

Referring to FIG. 2, the second embodiment is the same as the first embodiment except that BY4m is used as a light emitting dopant.

### Embodiment 3

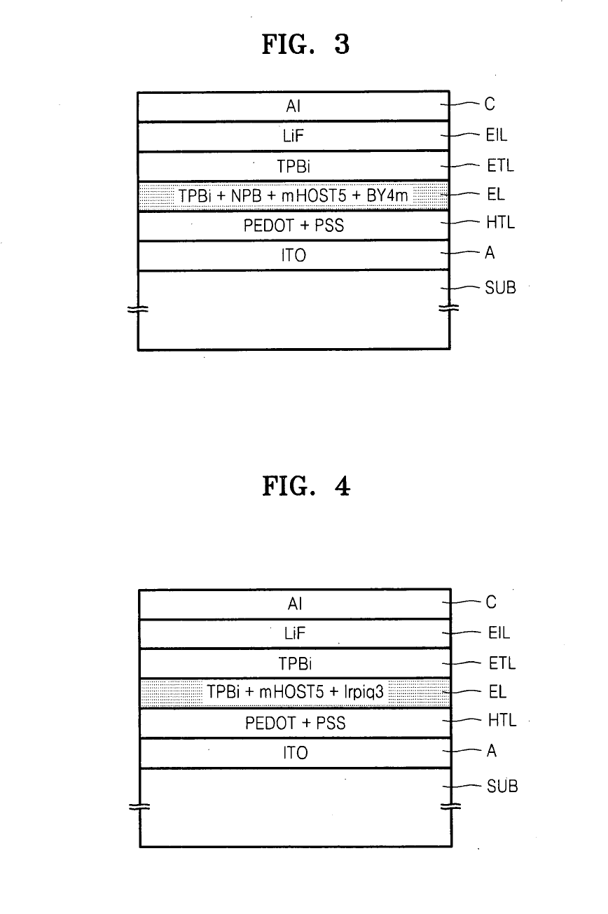

FIG. 3 is a cross-sectional view of an OLED and a method of manufacturing the OLED according to a third embodiment of the present invention.

Referring to FIG. 3, the third embodiment is the same as the first embodiment except that B1 in Table 2 is used as a small molecule host and BY4m is used as a light emitting dopant.

### Embodiment 4

FIG. 4 is a cross-sectional view of an OLED and a method of manufacturing the OLED according to a fourth embodiment of the present invention.

Referring to FIG. 4, the fourth embodiment is the same as the first embodiment except that A5 in Table 1 is used as a small molecule host and Irpiq3 is used as a light emitting dopant.

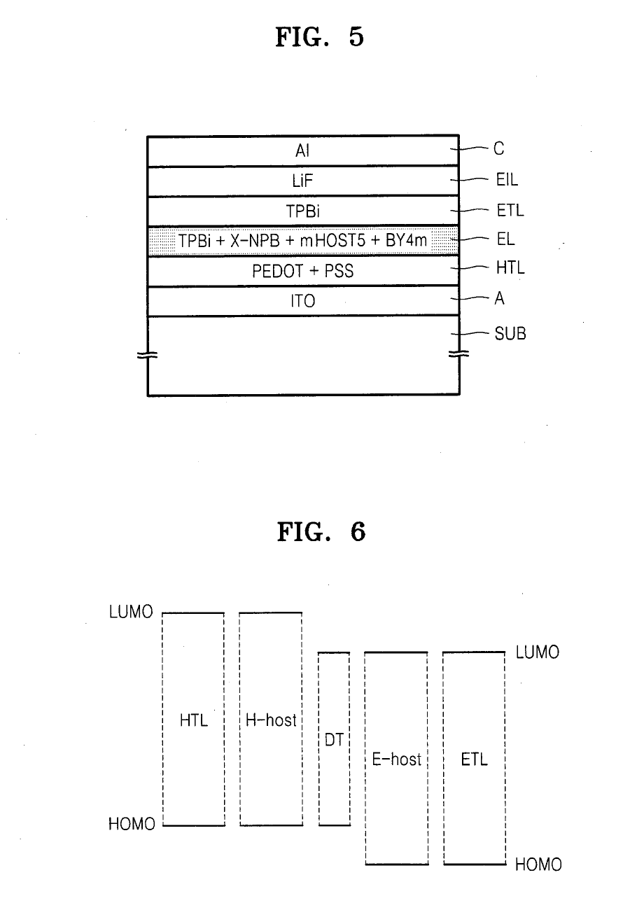

FIG. 5 is a cross-sectional view of an OLED and a method of manufacturing the OLED according to fifth through seventh embodiments of the present invention.

### Embodiment 5

The fifth embodiment of the present invention is the same as the second embodiment except that Spiro-NPB is used as the X-NPB of the small molecule host (TPBi+X-NPB+mHOST5).

### Embodiment 6

The sixth embodiment of the present invention is the same as the second embodiment except that DMFL-NPB is used as the X-NPB of the small molecule host (TPBi+X-NPB+mHOST5).

### Embodiment 7

The seventh embodiment of the present invention is the same as the second embodiment except that DPFL-NPB is used as the X-NPB of the small molecule host (TPBi+X-NPB+mHOST5).

The formation of the Electron Transporting Layer (ETL) can be omitted in the first through seventh embodiments of the present invention.

FIG. 6 is a schematic drawing showing HOMO and LUMO levels of each of a Hole Transporting Layer (HTL), an electron transporting host, a hole transporting host, and dopant and an Electron Transporting Layer (ETL) of OLEDs according to first through seventh embodiments of the present invention.

Referring to FIG. 6, the electron transporting host E-host has a HOMO level lower than the HOMO level of the Hole Transporting Layer (HTL), and the HOMO level difference may be greater than 0.5 eV, preferably, greater than 1.0 eV. The hole transporting host H-host has a LUMO level greater than the LUMO level of the Electron Transporting Layer (ETL), and the LUMO level difference may be greater than 0.5 eV, preferably, greater than 1.0 eV. Also, the electron transporting host E-host has a LUMO level within ±1 eV, preferably, within ±0.5 eV based on the LUMO level of the Electron Transporting Layer (ETL). Also, the electron transporting host E-host has a HOMO level within ±1 eV, preferably, ±0.5 eV based on the HOMO level of the Hole Transporting Layer (HTL). The light emitting dopant DT has a LUMO level within ±1 eV, preferably, ±0.5 eV based on the LUMO level of the electron transporting host E-host, and has a HOMO level within ±1 eV, preferably, ±0.5 eV based on the HOMO level of the hole transporting host H-host. The the Hole Transporting Layer (HTL), the hole transporting host H-host, and the light emitting dopant DT have similar HOMO levels, and the Electron Transporting Layer (ETL), the electron transporting host E-host, and the light emitting dopant DT have similar LUMO levels.

However, the HOMO level of the electron transporting host E-host is lower than the HOMO level of the Hole Transporting Layer (HTL), and the LUMO level of the hole transporting host H-host is higher than the LUMO level of the Electron Transporting Layer (ETL). Therefore, holes can be readily injected into the light emitting dopant DT from the the Hole Transporting Layer (HTL) through the hole transporting host H-host. Also, electrons can be readily injected into the light emitting dopant DT from the Electron Transporting Layer (ETL) through the electron transporting host E-host.

In the OLED according to the present embodiment, carrier trapping in the light emitting dopant DT occurs easily, thereby increasing luminous efficiency.

If the HOMO level of the electron transporting host E-host and the HOMO level of the Hole Transporting Layer (HTL) are similar to each other, holes can be injected into the electron transporting host E-host from the Hole Transporting Layer (HTL). The holes injected into the electron transporting host E-host cannot be effectively transported to the light emitting dopant DT, and thus, cannot contribute to the emission of light.

Also, if the LUMO level of the hole transporting host H-host and the LUMO level of the Electron Transporting Layer (ETL) are similar to each other, electrons can be injected into the hole transporting host H-host from the Electron Transporting Layer (ETL). The electrons injected into the hole transporting host H-host cannot be effectively transported to the light emitting dopant DT, and thus, cannot contribute to the emission of light.

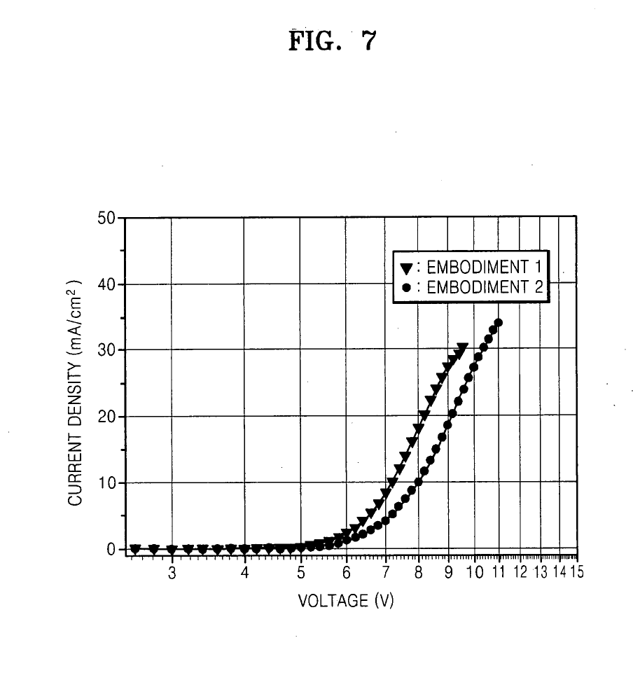

FIG. 7 is a graph of the variation of current density with respect to a voltage supplied to the OLEDs according to first and second embodiments of the present invention.

Referring to FIG. 7, the current densities of the OLEDs increase from the supplied voltage of 6V.

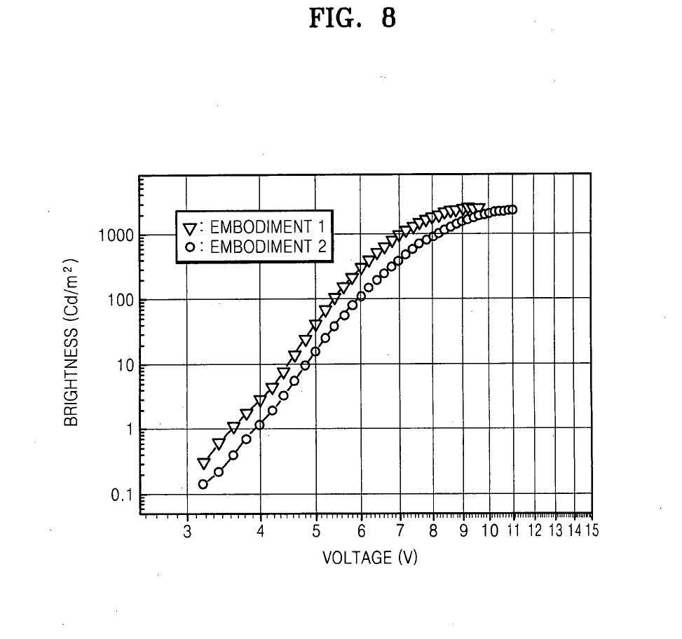

FIG. 8 is a graph of the variation of brightness with respect to a voltage supplied to the OLEDs according to first and second embodiments of the present invention.

Referring to FIG. 8, the brightness of the OLEDs increases as the voltage increases, and there is no big difference in brightness between the OLED according to the first embodiment and the OLED according to the second embodiment.

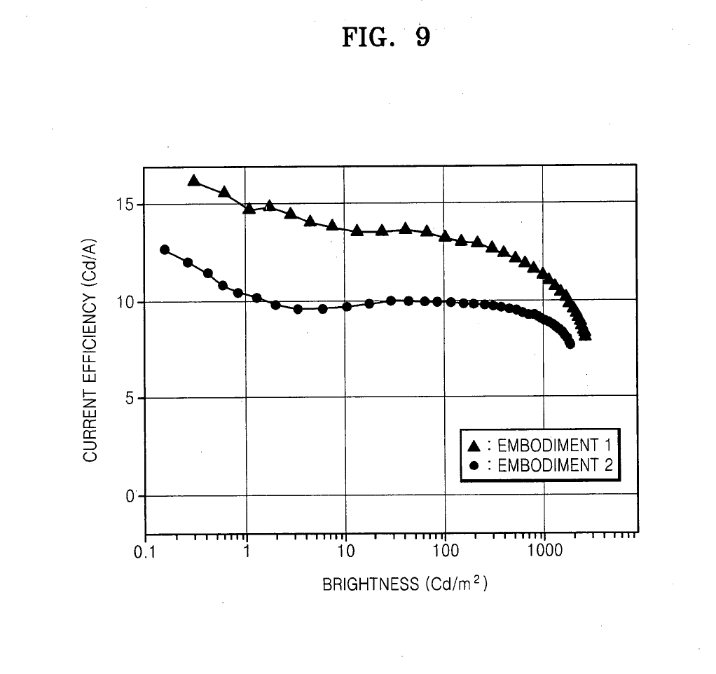

FIG. 9 is a graph derived from FIGS. 7 and 8, and showing the variation of current efficiency with respect to brightness of the OLEDs according to first and second embodiments of the present invention.

Referring to FIG. 9, it is seen that the OLEDs have current efficiency of approximately 10 to 15 cd/A.

It is known that the maximum current efficiency of a conventional OLED manufactured by a solution process using polyvinylcabazole (PVK) is approximately 8 cd/A.

That is, the OLED according to the present invention has higher current efficiency than the conventional OLED. Since the current efficiency is expressed as brightness vs. current, the higher current efficiency denotes a higher luminous efficiency.

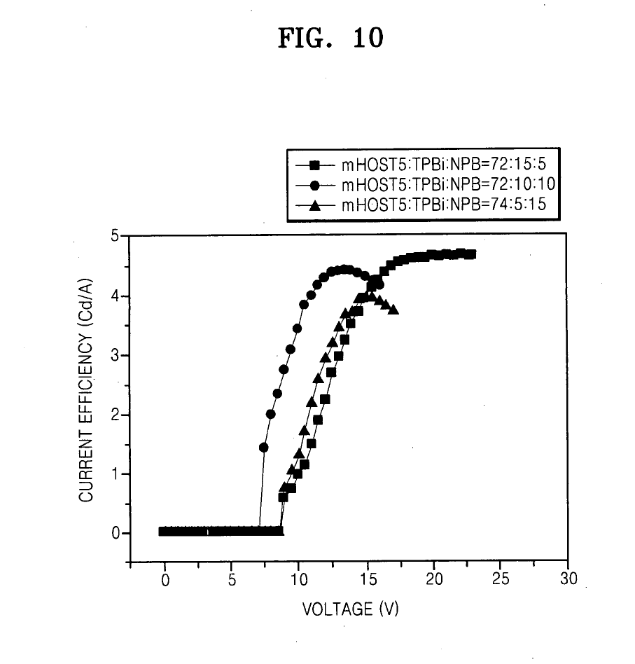

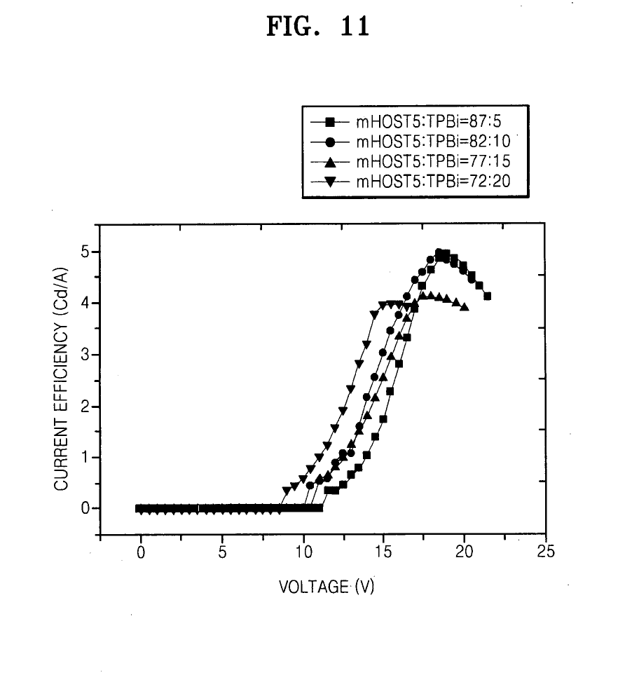

FIGS. 10 and 11 are graphs of the variation of current efficiency with respect to voltages supplied to the OLEDs according to third and fourth embodiments of the present invention. The kinds and compositions of the small molecule hosts used for the measurements are included in FIGS. 10 and 11.

Referring to FIGS. 10 and 11, the current efficiencies greatly increase from the supplied voltage of approximately 7V.

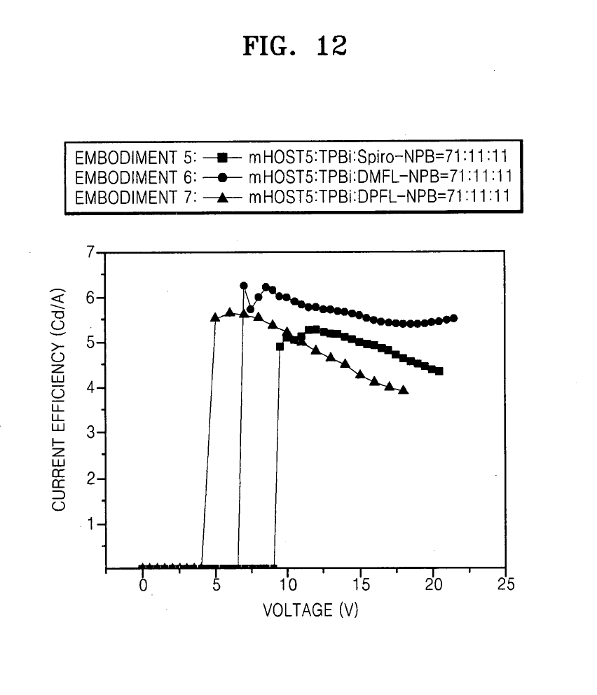

FIG. 12 is a graph of the variation of current efficiency with respect to a voltage supplied to the OLEDs according to fifth through seventh embodiments of the present invention. The kinds and compositions of the small molecule hosts used for the measurements are included in FIG. 12.

Referring to FIG. 12, the current efficiencies rapidly increase from the supplied voltage of approximately 4 to 8V, and the current efficiencies are approximately 4 to 7 cd/A.

As described above, a light emitting layer EL of an OLED according to the present invention is formed using a small molecule based solution process. Furthermore, to increase in the carrier trapping efficiency, the HOMO and the LUMO levels of the light emitting layer, the Hole Transporting Layer (HTL), and the Electron Transporting Layer (ETL) are appropriately controlled. Therefore, according to the present invention, an OLED having large screen size and long lifespan can be realized.

While the present invention has been particularly shown and described with reference to embodiments thereof, it should not be construed as being limited to the embodiments set forth herein. The materials for forming the anode A, the Hole Transporting Layer (HTL), the Electron Transporting Layer (ETL), the Electron Injection Layer (EIL), and the cathode C can be changed without departing from the spirit and scope of the present invention. Therefore, the scope of the present invention is defined not by the detailed description of the present invention but by the appended claims, and all differences within the scope will be construed as being included in the present invention.

What is claimed is:

1. An Organic Light Emitting Display (OLED) comprising:
a first electrode arranged on a substrate;
a Hole Transporting Layer (HTL) arranged on the first electrode;
a light Emitting Layer (EL) arranged on the HTL;
an Electron Transporting Layer (ETL) arranged on the light EL; and
a second electrode arranged on the ETL;
wherein the light EL includes a soluble hole transporting host, a soluble electron transporting host, and a soluble light emitting dopant;
wherein a difference of a Highest Occupied Molecular Orbital (HOMO) level between the HTL and the hole transporting host respectively and the light emitting dopant is 1 eV or less;
wherein a difference of a HOMO level between the HTL and the hole transporting host respectively and the electron transporting host is 0.5 eV or more;
wherein a difference of a Lowest Unoccupied Molecular Orbital (LUMO) level between the ETL and the electron transporting host respectively and the light emitting dopant is 1 eV or less; and
wherein a difference of a LUMO level between the ETL and the electron transporting host respectively and the hole transporting host is 0.5 eV or more.

2. The OLED of claim 1, wherein the light EL comprises a small molecule material.

3. The OLED of claim 1, wherein the HOMO level of the electron transporting host is lower than the HOMO level of the HTL by 0.5 eV or more.

4. The OLED of claim 1, wherein the LUMO level of the hole transporting host is higher than the LUMO level of the electron transporting layer by 0.5 eV or more.

5. The OLED of claim 1, wherein at least one of the electron transporting host and the ETL comprises a material selected from a group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

6. The OLED of claim 1, wherein at least one of the electron transporting host and the ETL comprises a material selected from a group consisting of TPBi, PBD, BCP, BAlq, and OXD7.

7. The OLED of claim 1, wherein the electron transporting host and the ETL comprise a same material.

8. The OLED of claim 1, wherein at least one of the hole transporting host and the HTL comprises a material selected from a group consisting of an oxadiazole compound having an amino substituent, a triphenylmethane compound having an amino substituent, a tertiary compound, a hydazone compound, a pyrazoline compound, an enamine compound, a styryl compound, a stilbene compound, and a carbazole compound.

9. The OLED of claim 1, wherein at least one of the hole transporting host and the HTL comprises a material selected from a group consisting of TBADN, NPB, TPD, Spiro-NPB, DMFL-NPB, DPFL-NPB, and mHOST5.

10. The OLED of claim 1, wherein the hole transporting host and the HTL comprise a same material.

11. The OLED of claim 1, wherein the HTL comprises a mixture film of PEDOT and PSS.

12. The OLED of claim 1, wherein the light EL further comprises a third soluble host to improve the characteristics of forming a thin film.

13. The OLED of claim 12, wherein the third soluble host comprises one of TPBi, TBADN, and mHOST5.

14. The OLED of claim 1, wherein the light emitting dopant comprises either an organic molecule or an organic-metal complex having either fluorescent or phosphorus characteristics.

15. The OLED of claim 1, wherein a content of the light emitting dopant in the light EL is in a range of 0.1 to 50 wt %.

16. The OLED of claim 1, wherein the light emitting dopant comprises one of Irpiq3 and BY4m.

17. The OLED of claim 1, wherein a ratio of a thickness of the light EL to a thickness of the ETL is in a range of from 1:100 to 100:1.

18. The OLED of claim 1, further comprising a Hole Injection Layer (HIL) arranged between the first electrode and the HTL.

19. The OLED of claim 1, further comprising an Electron Injection Layer (EIL) arranged between the ETL and the second electrode.

20. The OLED of claim 19, wherein the EIL comprises a LiF film.

21. An Organic Light Emitting Display (OLED) comprising:
a first electrode arranged on a substrate;
a Hole Transporting Layer (HTL) arranged on the first electrode;
a light Emitting Layer (EL) arranged on the HTL; and
a second electrode arranged on the light EL;
wherein the light EL includes a soluble hole transporting host, a soluble electron transporting host, and a soluble light emitting dopant;
wherein a difference of a Highest Occupied Molecular Orbital (HOMO) level between the HTL and the hole transporting host respectively and the light emitting dopant is 1 eV or less;
wherein a difference of a HOMO level between the HTL and the hole transporting host respectively and the electron transporting host is 0.5eV or more;
wherein a difference of a Lowest Unoccupied Molecular Orbital (LUMO) level between the electron transporting host and the light emitting dopant is 1 eV or less; and
wherein a difference of a LUMO level between the electron transporting host and the hole transporting host is 0.5 eV or more.

22. A method of manufacturing an Organic Light Emitting Display (OLED), the method comprising:
forming a first electrode on a substrate;
forming a Hole Transporting Layer (HTL) on the first electrode;
forming a light Emitting Layer (EL) on the HTL using a solution process;
forming an Electron Transporting Layer (ETL) on the light EL; and
forming a second electrode on the ETL;
wherein forming the light EL includes forming a mixed solution containing a soluble hole transporting host, a soluble electron transporting host, and a soluble light emitting dopant;
wherein a difference of a Highest Occupied Molecular Orbital (HOMO) level between the HTL and the hole transporting host respectively and the light emitting dopant is 1 eV or less;
wherein a difference of a HOMO level between the HTL and the hole transporting host respectively and the electron transporting host is 0.5 eV or more;
wherein a difference of a Lowest Unoccupied Molecular Orbital (LUMO) level between the ETL and the electron transporting host respectively and the light emitting dopant is 1 eV or less; and
wherein a difference of a LUMO level between the ETL and the electron transporting host respectively and the hole transporting host is 0.5 eV or more.

23. The method of claim 22, wherein the light EL is formed of a small molecule material.

24. The method of claim 22, wherein the solution process is selected from a group consisting of spin coating, inkjet printing, gravure printing, roll to roll processing, syringe injection, dip coating, spray coating, relief printing, lithography printing, flexography printing, and screen printing.

25. The method of claim 22, wherein at least one of the electron transporting host and the ETL is formed of a material selected from a group consisting of an anthracene compound, a phenanthracene compound, a pyrene compound, a perylene compound, a chrysene compound, a triphenylene compound, a fluoranthene compound, a periflanthene compound, an azole compound, a diazole compound, and a vinylene compound.

26. The method of claim 22, wherein at least one of the electron transporting host and the ETL is formed of a material selected from a group consisting of TPBi, PBD, BCP, BAlq, and OXD7.

27. The method of claim 22, wherein at least one of the hole transporting host and the HTL is formed of a material selected from a group consisting of an oxadiazole compound having an amino substituent, a triphenylmethane compound having an amino substituent, a tertiary compound, a hydazone compound, a pyrazoline compound, an enamine compound, a styryl compound, a stilbene compound, and a carbazole compound.

28. The method of claim 22, wherein at least one of the hole transporting host and the HTL is formed of a material selected from a group consisting of TBADN, NPB, TPD, Spiro-NPB, DMFL-NPB, DPFL-NPB, and mHOST5.

29. The method of claim 22, wherein the light EL further comprises a third soluble host to improve the characteristics of forming a thin film.

30. The method of claim 29, wherein the third soluble host comprises one of TPBi, TBADN, and mHOST5.

31. The method of claim 22, wherein the HTL is formed of a mixture film of PEDOT and PSS.

32. The method of claim 22, wherein the light emitting dopant is either an organic molecule or an organic-metal complex having either fluorescent or phosphorus characteristics.

33. The method of claim 22, wherein the light emitting dopant is one of Irpiq3 and BY4m.

34. A method of manufacturing an Organic Light Emitting Display (OLED), the method comprising:
forming a first electrode on a substrate;
forming a Hole Transporting Layer (HTL) on the first electrode;
forming a light Emitting Layer (EL) on the HTL using a solution process; and
forming a second electrode on the light EL;
wherein forming the light EL includes forming a mixed solution containing a soluble hole transporting host, a soluble electron transporting host, and a soluble light emitting dopant;
wherein a difference of a Highest Occupied Molecular Orbital (HOMO) level between the HTL and the hole transporting host respectively and the light emitting dopant is 1 eV or less;
wherein a difference of a HOMO level between the HTL and the hole transporting host respectively and the electron transporting host is 0.5 eV or more;
wherein a difference of a Lowest Unoccupied Molecular Orbital (LUMO) level between the electron transporting host and the light emitting dopant is 1 eV or less; and
wherein a difference of a LUMO level between the electron transporting host and the hole transporting host is 0.5 eV or more.
